(19) United States
(12) Patent Application Publication
(10) Pub. No.: US 2011/0201185 A1
(43) Pub. Date: Aug. 18, 2011

(54) Method to improve transistor performance matching for plasma-assisted source/drain formation

(75) Inventors: Devesh Kumar Datta, Singapore (SG); Keen Wah Chow, Singapore (SG); Chun Kit Kwok, Singapore (SG); Wai Khin Joshua Lee, Singapore (SG)

(73) Assignee: TECH Semiconductor Singapore Pte Ltd

(21) Appl. No.: 12/658,931

(22) Filed: Feb. 17, 2010

(51) Int. Cl. H01L 21/3213

(52) U.S. Cl. 438/513; 257/E21.311

(57) ABSTRACT

Methods to dope transistors with equal or similar dopant concentration are described. In a first alternative, a slow dose per pulse ramp during plasma-assisted doping is proposed. This method results in a thinner surface deposited layer resulting in equal dopant concentration throughout the area. In a second alternative, transistors are placed away from the mask edge in order to achieve equal dopant concentration.

### BACKGROUND OF THE INVENTION

(1) Field of the Invention

The invention relates to a method of source/drain implantation, and more particularly, to a method of improving transistor performance matching for plasma-assisted source/drain formation.

(2) Description of the Related Art

In semiconductor manufacturing, extremely pure (also known as intrinsic) semiconductors, for example, silicon (Si), germanium (Ge), silicon germanium (SiGe), gallium arsenide (GaAs) and silicon carbide (SiC), are intentionally doped with impurities to change their electrical properties. For Group 4 semiconductors, the most common dopants are acceptors from Group 3 of the periodic table, such as boron (B), and donors from Group 5 of the periodic table, such as arsenic (As) and phosphorous (P). Acceptors form p-type semiconductors where the majority carriers are holes while donors form n-type semiconductors where the majority carriers are electrons. Lightly- and moderately doped (also known as extrinsic) semiconductors are components of many devices, including diodes and transistors.

Transistors, which are used to amplify or switch electronic signals, are made of both p-type and n-type semiconductors. For example, bipolar transistors consist of two p-n junctions joined in series to form n-p-n or p-n-p transistors. For both types, there are three terminals, namely emitter, base and collector. The emitter emits the charge, the collector collects the charge, and the base between the emitter and the collector controls the collector current. For a field-effect transistor, the terminals are labeled source, gate and drain respectively, and a voltage at the gate controls the current between the source and the drain.

As device geometries continue to shrink, the junction depth of the source and drain regions of a transistor must be made shallower to prevent short channel effect and its accompanying hot carrier effect that degrade device performance. For source/drain (S/D) junctions which are doped, low energy ion implantation is needed to obtain shallow depth profiles. Plasma-assisted doping is widely used because it offers unique advantages over conventional beamline technologies, including ultra-low energy, high throughput, low cost and small footprint.

During plasma-assisted doping, dopant gas is partially ionized to form plasma containing positive ions, negative electrons and neutral molecules. A negative bias voltage is applied to the wafer and positive ions in the plasma are accelerated across the sheath and implanted within the wafer. Some of the ions fall on the top surface or sidewall of the photoresist mask that covers the regions not intended for plasma-assisted doping, and are repelled from the positively charged surface onto the regions requiring plasma-assisted doping. In the process, the ions lose energy and do not have sufficient energy to penetrate the wafer. This results in surface deposition, rather than implantation, which blocks the implant. Due to the projectile of the scattered ions, the deposited surface layer will be thicker in the center than at the mask edge. Hence, dopant concentration will decrease with increasing distance from the mask edge. Non-uniform dopant profile leads to differences in the characteristics of similar transistors located at different areas of the implanted regions, such as threshold voltage. Such imbalance affects the proper functionality of circuits, especially those which require the electrical performance to be matched between two or more transistors.

This phenomenon is only observed for low energy ion implantation because for high energy ion implantation, the scattered ions will have sufficient energy to penetrate the wafer surface. Therefore, the opposite is observed. A number of papers have reported higher dopant concentration at the center than at the mask edge due to the contribution by scattered ions. For example, see Drennan et al., “Implications of Proximity Effects for Analog Design,” IEEE Custom Integrated Circuits Conference, 2006; pp. 169-176 and Hook et al., “Lateral Ion Implant Straggle and Mask Proximity Effect,” IEEE Transactions on Electron Devices 50 (9) 2003, pp. 1946-1951.

The plasma deposited surface layer is more pronounced when plasma-assisted doping is carried out with a hydride of the dopant species, e.g. diborane (B₂H₆) for p-channel source/drain implant and phosphine (PH₃) for n-channel source/drain implant, due to the relative ease of dissociation of these gases in the plasma compared to their fluoride counterparts, e.g. BF₃ and PF₃. This observation was disclosed in U.S. Pat. No. 7,137,354 to Collins et al. However, the latter is not viable for p-channel S/D doping as fluorine enhances out-diffusion of boron resulting in higher contact resistance, and causes unintentional etching of the underlying layer. Therefore, a method to obtain a similar dose profile for different transistors when using hydrides of the dopant gas is needed.

Currently, there are only a few known methods to overcome the deposited surface layers. They include those disclosed in WO2004/013371, WO2006/099438 and US2006/0099830 and U.S. Pat. No. 7,528,389. WO2004/013371 to Walther and Radovanov teaches a method to remove the deposited surface layers by dilution gas sputtering. In another approach, the wafer is heated to promote evaporation of the deposited material. WO2006/099438 to Fang et al teaches a method to achieve dose uniformity by applying a bias voltage that increases with the increasing deposited surface layer thickness so that dopant ions have sufficient energy to penetrate the deposited surface layer into the wafer. US2006/0099830 to Walther et al teaches a method for limiting the formation of the deposited surface layers by using fluorides or chlorides of the dopant gas, e.g. BF₃ and PF₃, instead of its hydrides, e.g. B₂H₆ and PH₃, as they dissociate less easily. U.S. Pat. No. 7,528,389 to Fang et al teaches that ramping is adjusted to adjust the dopant concentration. The number of pulses and pulse duration are selected to provide the desired impurity dose. Duty cycle ramping is used to prevent wafer surface arcing, not to neutralize charges on the photoresist surface. Voltage bias is ramped according to the thickness of the deposited surface layer. The method focuses on maintaining the depth profile of the dopant, and minimizing the dopant spread in vertical and lateral directions.

According to these above disclosures by Varian Semiconductor Equipment Associates, Inc., materials deposited on the wafer surface are neutral particles that result from the dissociation of dopant gas. These neutrals and ions deposit randomly on the wafer surface. Thus, the surface deposited layer is not expected to show a dome-shaped profile. On the other hand, our observations suggest that materials deposited on the wafer surface are positive ions that repel from the like-charged photoresist mask. As a result, the deposited surface layer thickness is sensitive to photoresist mask patterns, a problem that was not considered in the above disclosures.

### SUMMARY OF THE INVENTION

It is the primary objective of the present invention to dope transistors with equal or similar dopant concentration.

It is another objective of the invention to dope transistors with equal or similar dopant concentration by using a slow dose per pulse ramp during plasma-assisted doping.

It is a further objective of the invention to dope transistors with equal or similar dopant concentration by placing transistors in a region where surface deposition thickness is constant.

Yet another objective of the invention is to dope transistors with equal or similar dopant concentration by placing transistors away from the mask edge.

In accordance with the objectives of the invention, a slow dose per pulse ramp is used during plasma-assisted doping.

Also in accordance with the objectives of the invention, the transistor layout is changed so that transistors are placed in the region where surface deposition thickness is constant to minimize variation between the dopant profiles of a transistor pair. Alternatively, the mask edge, where there is huge variation in surface deposition thickness, can be shifted further from the transistor.

### BRIEF DESCRIPTION OF THE DRAWINGS

In the accompanying drawings forming a material part of this description, there is shown:

FIG. 1A is a cross-sectional representation of a surface deposited layer of the prior art.

FIG. 1B is a top view of the surface deposited layer of FIG. 1A.

FIG. 2 is a cross-sectional representation of a surface deposited layer of a first preferred embodiment of the present invention.

FIG. 3 is a schematic representation of a duty cycle of a first preferred embodiment of the present invention.

FIG. 4 is a graphical representation of the ramp set up of a first preferred embodiment of the present invention.

FIGS. 5A and 5B are cross-sectional representations showing why the duty cycle of the present invention increases over time.

FIG. 6 is a graphical representation of the relationship between implant cycle factor and drive current mismatch in the first preferred embodiment of the present invention.

FIG. 7 is a graphical representation of the relationship between deposition thickness and edge of the photoresist mask in a second preferred embodiment of the present invention.

FIG. 8 is a cross-sectional representation of a transistor and mask layout in the second preferred embodiment of the present invention.

### DETAILED DESCRIPTION OF THE INVENTION

The present invention provides two methods for doping transistors with equal or similar dopant concentration. In a first preferred embodiment of the invention, according to the first method, a slow dose per pulse ramp is used during plasma-assisted doping. In a second preferred embodiment of the invention, the transistor or mask layout is changed to provide consistent doping concentration.

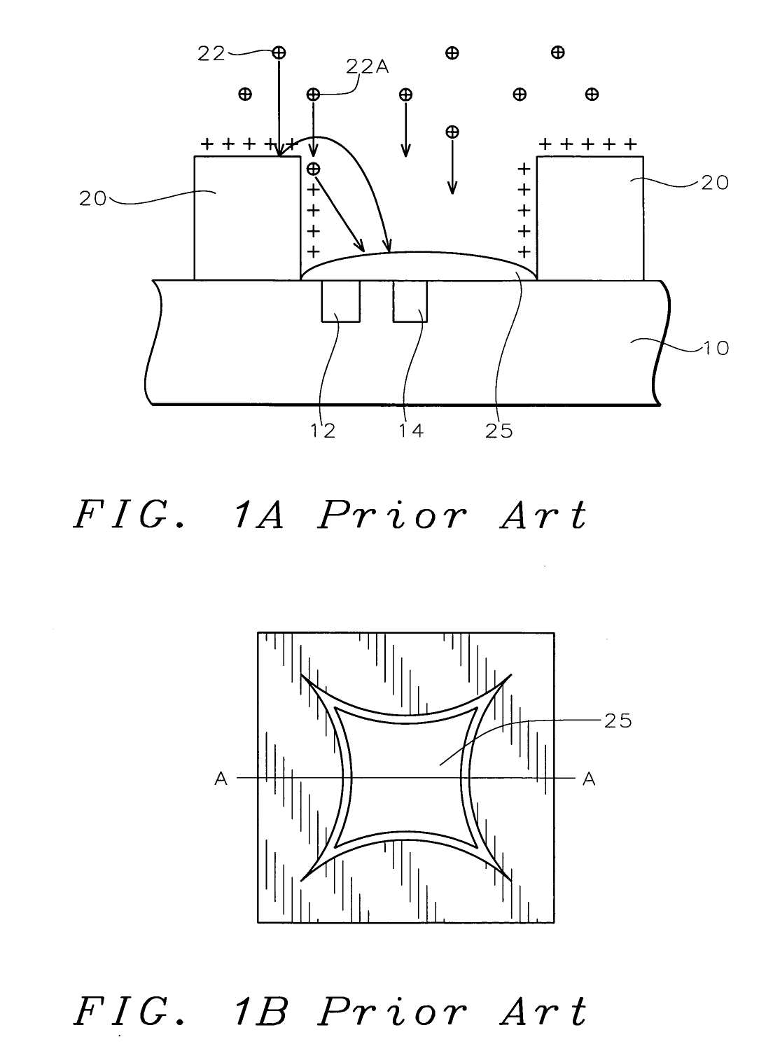

FIG. 1B is a top view and FIG. 1A is a side view along line A-A of FIG. 1B. As shown in FIGS. 1A and 1B, during plasma-assisted doping, some of the positive ions 22 in the plasma fall on the photoresist mask 20 that covers the regions of the substrate 10 not intended for plasma-assisted doping. These ions 22 are repelled from the positively charged surface of the photoresist mask 20 and fall onto the regions requiring plasma-assisted doping. Additionally, some ions 22A are repelled from the sidewall of the photoresist mask and fall onto the regions requiring plasma-assisted doping. In the process, the ions lose energy and do not have sufficient energy to penetrate the wafer. This results in surface deposition 25, rather than implantation. FIG. 1B shows a top view of the surface deposited layer 25. The surface deposition 25 further blocks the implant. Due to the projectile of the scattered ions, the deposited surface layer will be thicker in the center than at the mask edge, as shown in FIG. 1A. Thus, transistor 12 receives a higher concentration of dopants than does transistor 14. Since transistor 12 is located near the edge of the mask 20, the surface deposited layer 25 overlying it is not so thick as the layer 25 overlying transistor 14, so more of the dopant ions 22 penetrate into the transistor 12 than penetrate into the transistor 14.

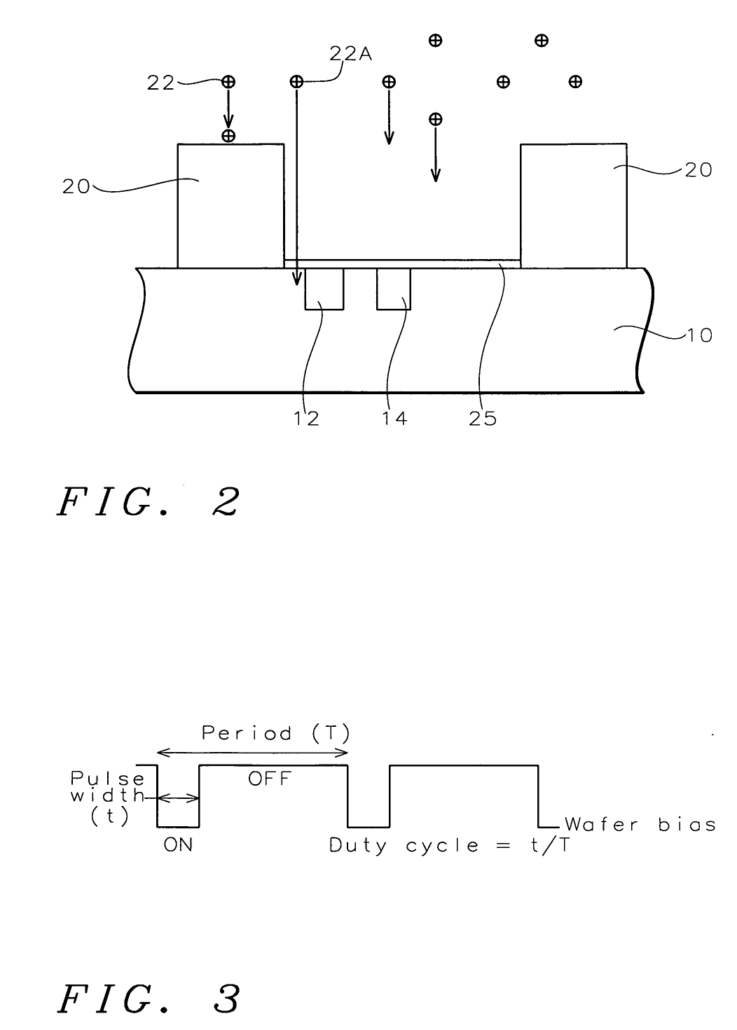

The first preferred embodiment of the invention will now be described with reference to FIGS. 2-6. Plasma-assisted doping neutralizes wafer surfaces in a sequential fashion, using the plasma after the end of the bias pulse as a form of in situ plasma flood system. Using a slow dose per pulse ramp will allow a lower charge buildup and help the charges on the photoresist mask to dissipate. This way, the ions 22 will not be repelled by the photoresist surface, but will instead remain on the photoresist surface. The ions 22A that fall on the sidewall of the photoresist mask will behave like any other ions that fall on the open surface. They will fall vertically down and be implanted into the wafer 10 if they have sufficient energy or deposit on the surface if they do not. As a result, the surface deposited layer is expected to be rather uniform and not show the dome-shaped profile of the prior art. This is illustrated in FIG. 2.

The plasma-assisted ion implantation process of the present invention results in a surface deposited layer 25 consisting of neutral particles and low energy ions that randomly fall on the wafer surface. The contribution from repelled ions which gives rise to non-uniformity of the surface deposited layer is negligible, resulting in a uniform thickness layer 25 of minimal thickness. With the reduction of the plasma deposited surface layer 25, the ion implant will not be blocked and a uniform dose profile for a transistor pair can be obtained.

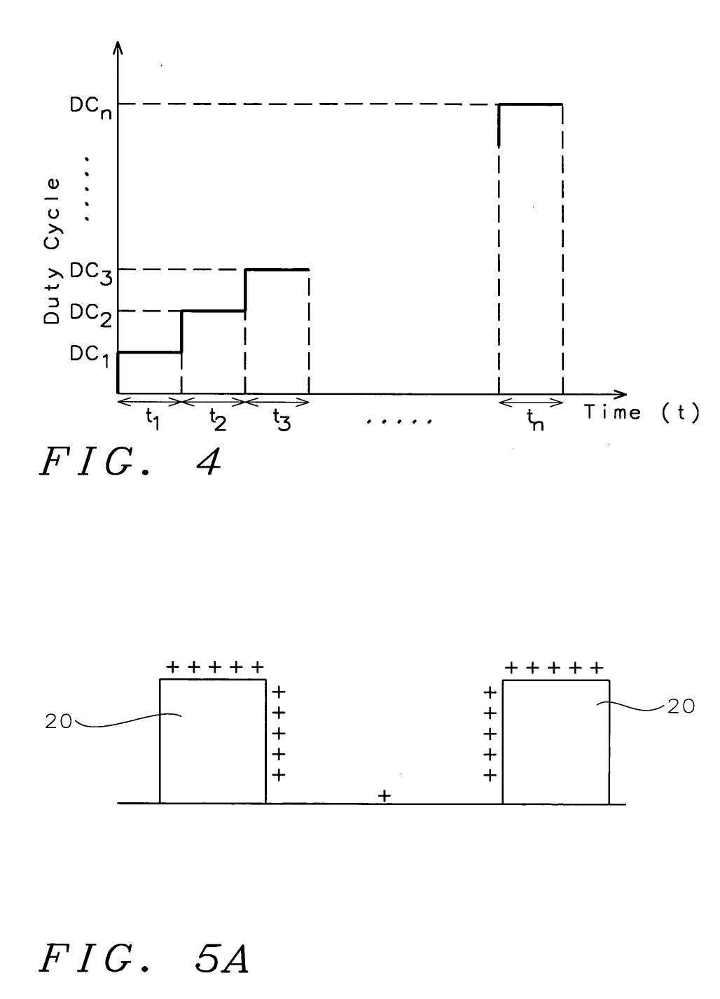

The plasma-assisted doping of the present invention uses a slow dose per pulse ramp during plasma-assisted doping. Instead of introducing the dopant gas at a fixed duty cycle, pulse width and dose, dopant gas, preferably comprising a hydride of the dopant species (e.g. B₂H₆, PH₃ and AsH₃), is introduced into the plasma-assisted doping chamber at low duty cycle, pulse width and dose at the beginning of the process. The duty cycle gradually increases until the desired dopant concentration is obtained. The duty cycle increases in a step function as shown in FIG. 4. Pulse width also increases since it is related to duty cycle (see FIG. 3). The transition from one duty cycle to the next duty cycle occurs when the total accumulated implant dose reaches a pre-defined level. Implant dose is monitored in real-time using an implant dose monitor, such as a Faraday cup.

Duty cycle is defined as the ratio of pulse width to period, as shown in FIG. 3. A 10% duty cycle with a period of 100 μs will have pulse-on time of 10 μs where positive or negative bias voltage is applied to accelerate ions towards the wafer, and a pulse-off time of 90 μs where bias voltage is turned off. Bias voltage remains constant when it is turned on. A lower duty cycle, and hence a longer pulse-off time, will mean that the charges accumulated on the photoresist have more time to dissipate which minimizes the chance of ions' scattering out of the photoresist and depositing on the wafer surface. This means that the ions that land on the photoresist will not be repelled and deposit as a surface layer, but will instead remain on the photoresist until the ions are neutralized by the plasma.

As a result, ion implant will not be blocked and a uniform dose profile can be obtained. Reduced surface deposition thickness also means that less effort is needed to remove the surface layer after plasma-assisted doping, e.g. by hot de-ionized water clean, hot sulfuric peroxide clean, plasma-assisted strip, etc.

Dose per pulse (DPP) ramp is measured in terms of a newly-coined implant cycle factor (ICF) which is defined as:

$$ICF = \sqrt{{\sum }_{i = 1}^{n} {( {DC}_{i} \times {t}_{i} )}^{2}}$$

where DCᵢ is the duty cycle and t is the process time of step i which is a function of pulse width and dose (refer to FIG. 4 for the graphical representation of the ramp setup).

The above equation is given by way of example only. It will be apparent to those skilled in the art that numerous variations and modifications to the above equation may be made without departing from the spirit and scope of the invention. It should also be understood that although an equal step increase is shown in FIG. 4, an uneven increase may also be utilized within the scope of the present invention.

At the beginning of the plasma-assisted doping process, the top surface and sidewall of the photoresist mask are more charged up than the open surface between the photoresist mask as it is nearer to the dopant source (see FIG. 5A). Ions are repelled from the charged top surface or sidewall of the photoresist mask into the open surface, resulting in a dome-shaped profile for the surface deposited layer. However, as the plasma-assisted doping process continues, the open surface also becomes charged up and there is less charge imbalance between the open surface and the top surface or sidewall of the photoresist mask (see FIG. 5B). Ions are now randomly deflected off the surfaces, giving rise to a more uniform surface deposited layer. Therefore, a lower duty cycle is required at the beginning of the plasma-assisted doping process to dissipate the charges on the top surface and sidewall of the photoresist mask so that the dome-shaped profile will be less prominent, while a higher duty cycle can be afforded at the later stages of the plasma-assisted doping process. For example, a preferred beginning condition is a duty cycle of about 2-5% and a preferred ending condition is a duty cycle of about 30-50%.

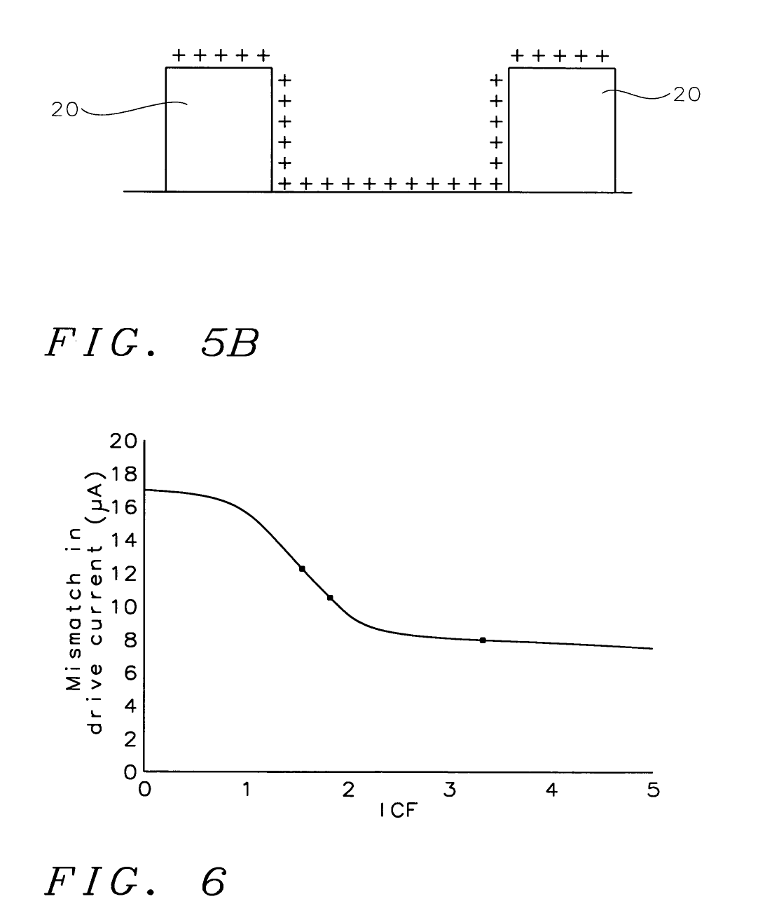

FIG. 6 graphically illustrates implant cycle factor (ICE) as it relates to the mismatch in drive current. As shown in the graph, ICF is preferably between 1 and 5. If ICF is less than 1, the mismatch in drive current between the transistor pair, a performance measurement of the sense amplifier, will exceed the specification limit. Besides drive current, other performance measures may include, but are not limited to, threshold voltage, transconductance and write timings. Beyond an ICF of 5, the cycle time will be too long, leading to lower production efficiency.

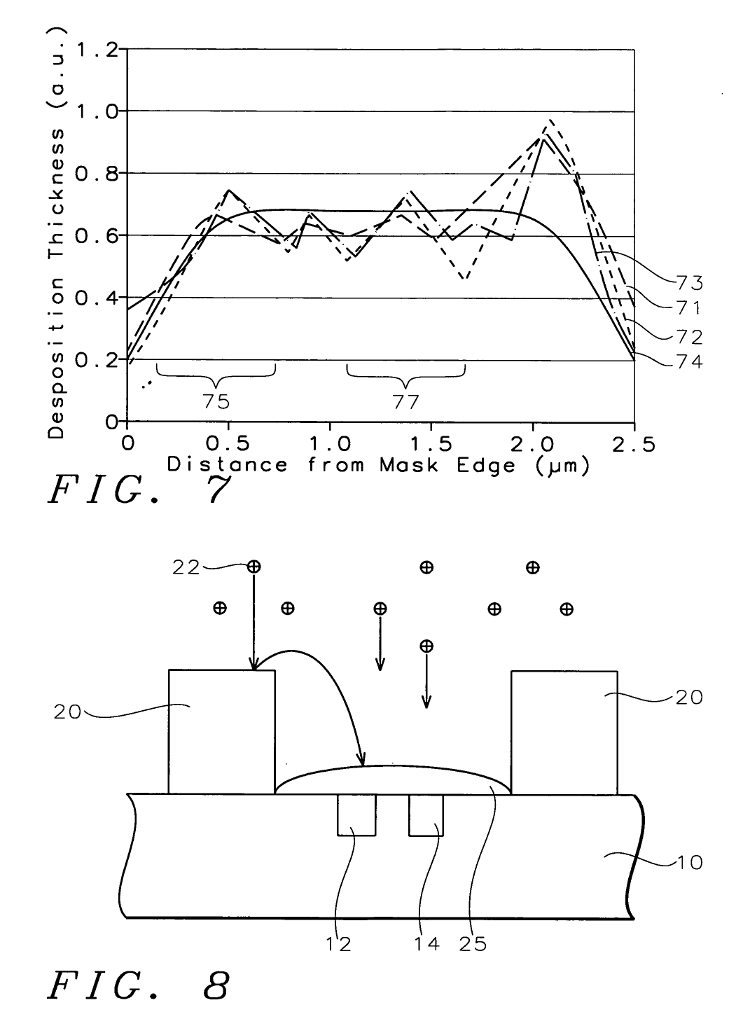

The second preferred embodiment of the invention will now be described with reference to FIGS. 7 and 8. The second method involves changing the transistor or mask layout. This involves placing the transistors in the region away from the mask edge or moving the mask edge away from the transistors. As shown by the simulation results in FIG. 7, there is a large variation in deposition thickness near the photoresist mask. Lines 71, 72, and 73 show the deposition thickness as a function of edge distance when the photoresist mask 20 has a thickness of 0.4 μm, 0.8 μm, and 1.2 μm, respectively. Line 74 is a smoothed line representing the general trend of deposition thickness with respect to edge distance. The area 75 near the mask edge has a much larger variation in deposition thickness than does the area 77 away from the mask edges. In FIG. 1, area 75 corresponds to the location of transistor 12 and area 77 corresponds to the location of transistor 14.

Maintaining a minimum distance between the mask edge and the transistors will ensure that the transistors are in the region where deposition thickness is constant so that there is negligible variation between the dopant profiles of transistor pair. This minimum distance from edge of the photoresist mask is dependent on the spacing between the photoresist masks, and can be determined from simulation. The minimum distance is preferably at least 0.50 μm. FIG. 8 illustrates one possible layout where transistor 12 and 14 are both spaced far enough from the mask 20 edge that the deposition thickness above each transistor is nearly constant. Thus, the resulting dopant concentration of both transistors 12 and 14 is the same.

It should be understood that although the above description illustrates a transistor pair, one skilled in the art would appreciate that the present invention can be applied to more than two transistors where it is important to have equal or similar dopant concentration. It can also be applied to devices other than transistors where uniform dopant profile is desired.

The process of the present invention focuses on minimizing transistor mismatch by: 1) using duty cycle ramping to neutralize charges on the photoresist surface, or 2) changing the design, such as mask layout, to fix transistor mismatch.

In conclusion, we note the following advantages of the present invention:
Ability to dope a transistor pair with equal or similar dopant concentration.
Reduced variation in transistor mismatch due to chamber condition as chamber condition affects surface deposition.
Delay the need for more sophisticated circuit design that delivers better matched electrical performance between two or more transistors.
Wider lithography margin due to improved resist thickness and profile.
Easy to implement.

Although the preferred embodiment of the present invention has been illustrated, and that form has been described in detail, it will be readily understood by those skilled in the art that various modifications may be made therein without departing from the spirit of the invention or from the scope of the appended claims.

What is claimed is:

1. A method for minimizing device mismatch by providing consistent doping concentration in a plasma-assisted ion implantation process comprising:
providing two or more devices in a semiconductor substrate;
providing a photoresist mask exposing said two or more devices; and
implanting ions into said two or more devices to obtain said desired dopant concentration wherein said implanting comprises:
introducing dopant gas into a plasma-assisted doping chamber at low duty cycle, pulse width and dose at the beginning of said plasma-assisted ion implantation process; and
gradually increasing said duty cycle with each successive pulse until a desired dopant concentration is obtained.

2. The method according to claim 1 wherein said devices comprise transistors.

3. The method according to claim 1 wherein said dopant gas comprises a hydride of a dopant species.

4. The method according to claim 1 wherein said duty cycle is defined as the ratio of pulse width to the period between pulses.

5. The method according to claim 1 wherein said gradually increasing duty cycle gives charges accumulated on said photoresist mask time to dissipate thereby minimizing the chance of said ions being repelled from said photoresist mask and depositing on said substrate thereby blocking implantation.

6. The method according to claim 1 wherein said duty cycle increases in a step function.

7. The method according to claim 1 wherein a preferred beginning condition is a duty cycle of between about 2% and 5% and a preferred ending condition is a duty cycle of between about 30% and 50%.

8. A method for providing consistent doping concentration in a plasma-assisted ion implantation process comprising:
introducing dopant gas into a plasma-assisted doping chamber at low duty cycle, pulse width and dose at the beginning of said plasma-assisted ion implantation process; and
gradually increasing said duty cycle with each successive pulse until a desired dopant concentration is obtained.

9. The method according to claim 8 wherein said dopant gas comprises a hydride of a dopant species.

10. The method according to claim 8 wherein said duty cycle is defined as the ratio of pulse width to the period between pulses.

11. The method according to claim 8 wherein said duty cycle increases in a step function.

12. The method according to claim 8 wherein a preferred beginning condition is a duty cycle of between about 2% and 5% and a preferred ending condition is a duty cycle of between about 30% and 50%.

13. The method according to claim 8 further comprising:
providing two or more devices in a semiconductor substrate;
providing a photoresist mask exposing said two or more devices; and
implanting ions into said two or more devices to obtain said desired dopant concentration wherein said gradually increasing duty cycle gives charges accumulated on said photoresist mask time to dissipate thereby minimizing the chance of said ions being repelled from said photoresist mask and depositing on said substrate thereby blocking implantation.

14. A method for minimizing device mismatch by providing consistent doping concentration in a plasma-assisted ion implantation process comprising:
providing a device or mask layout wherein two or more devices are each placed at a distance from a photoresist mask edge in order to provide consistent doping concentration from ions implanted in said plasma-assisted ion implantation process.

15. The method according to claim 14 further comprising:
providing said two or more devices in a semiconductor substrate;
providing said photoresist mask exposing said two or more devices; and
implanting said ions into said two or more devices to obtain said desired dopant concentration wherein some of said ions are repelled from said photoresist mask and deposited on said substrate in a surface layer, wherein said surface layer has a constant thickness in a central area more than said distance from said edge of said photoresist mask, and wherein said constant thickness surface layer allows consistent doping concentration in said two or more devices.

16. The method according to claim 14 wherein said distance is dependent on spacing between portions of said photoresist mask.

17. The method according to claim 14 wherein said distance is at least 0.50 μm.
